(19) United States
(12) Patent Application Publication
(10) Pub. No.: US 2025/0340989 A1
(43) Pub. Date: Nov. 6, 2025

(54) FILM FORMATION SIMULATION METHOD, FILM FORMATION SIMULATION PROGRAM, SIMULATION) SIMULATOR, AND FILM FORMATION DEVICE

(71) Applicant: SONY SEMICONDUCTOR SOLUTIONS CORPORATION, KANAGAWA (JP)

(72) Inventor: Nobuyuki KUBOI, KANAGAWA (JP)

(21) Appl. No.: 18/870,989

(22) PCT Filed: Apr. 24, 2023
(86) PCT No.: PCT/JP2023/016171

§ 371 Date: Dec. 2, 2024

(30) Foreign Application Priority Data
Jun. 10, 2022 (JP) 2022-094465

(51) Int. Cl. C23C 16/52

(52) U.S. Cl. CPC C23C 16/52

(57) ABSTRACT

A film formation simulation method according to an embodiment of the present disclosure includes a step of generating representative particles depending on an incident radical flux, and calculating adhesion, desorption, migration, and deposition of the respective representative particles to/from/on a film formation surface according to probability. The above-described step of the film formation simulation method includes expressing film quality and film coverage on the film formation surface by calculating the deposition as voxels imparted with status information indicating a bonded state or unbound state between the representative particles and the film formation surface.

### TECHNICAL FIELD

The present disclosure relates to a film formation simulation method that simulates a shape of a surface to be processed in a film formation process (a film formation surface that is a film formation target), a film formation simulation program that executes the film formation simulation method, and a film formation simulator. In addition, the present disclosure relates to a film formation device including the film formation simulator.

Key processes of semiconductor device manufacture include a film formation process that forms or embeds a thin film (on the order of nanometers) on a pattern. As demands for high functionalization of semiconductor devices have increased in recent years, more semiconductor devices have complexly stacked structures with a mixture of high and low aspect ratios, and the difficulty of embedding such a pattern in a film formation process has increased. Therefore, it has become more important to predict film coverage and film quality (for example, density, defect density, permeability, adhesiveness, and the like) relying on process conditions. In such a situation, numerical simulation for film formation processes is useful as one of prediction techniques.

For example, Patent Literature 1 uses Monte Carlo methods to calculate adhesion/desorption of gas particles to/from a pattern surface, migration relying on substrate temperature, and deposition of particles in consideration of influence of surface asperity, and to predict morphology of a film. In addition, Patent Literature 1 further proposes a method of predicting film quality distribution by using a database of film quality associated with morphology constructed in advance on a basis of molecular dynamics (MD) calculation or first principle calculation.

### CITATION LIST

### Patent Literature

Patent Literature 1: Japanese Unexamined Patent Application Publication No. 2017-204757

### SUMMARY OF THE INVENTION

However, since the method disclosed in Patent Literature 1 calculates irradiated gas by using the Monte Carlo methods, its accuracy and calculation time heavily rely on the number of particles used in the Monte Carlo methods. In addition, to calculate film quality, it is necessary to separately prepare a database relying on morphology and a gas flux according to molecular dynamics (MD) calculation or first principle calculation. Therefore, it takes quite time and labor for preparation before it can actually become usable as a simulation tool. Accordingly, it is desirable to provide a film formation simulation method, film formation simulation program, and film formation simulator that make it possible to shorten the calculation time and improve calculation accuracy, and a film formation device including such a film formation simulator.

A film formation simulation method according to an embodiment of the present disclosure includes a step of generating representative particles depending on an incident radical flux, and calculating adhesion, desorption, migration, and deposition of the respective representative particles to/from/on a film formation surface according to probability. The above-described step of the film formation simulation method includes expressing film quality and film coverage on the film formation surface by calculating the deposition as voxels imparted with status information indicating a bonded state or unbound state between the representative particles and the film formation surface.

A film formation simulation program according to an embodiment of the present disclosure includes an input section, an arithmetic section, and an output section. The input section acquires a film formation condition. The arithmetic section generates representative particles depending on an incident radical flux under the film formation condition acquired by the input section, and calculates adhesion, desorption, migration, and deposition of the respective representative particles to/from/on a film formation surface according to probability. The output section outputs an arithmetic result obtained by the arithmetic section. The arithmetic section expresses film quality and film coverage on the film formation surface by calculating the deposition as voxels imparted with status information indicating a bonded state or unbound state between the representative particles and the film formation surface.

A film formation simulator according to an embodiment of the present disclosure includes an input section, an arithmetic section, and an output section. The input section acquires a film formation condition. The arithmetic section generates representative particles depending on an incident radical flux under the film formation condition acquired by the input section, and calculates adhesion, desorption, migration, and deposition of the respective representative particles to/from/on a film formation surface according to probability. The output section outputs an arithmetic result obtained by the arithmetic section. The arithmetic section expresses film quality and film coverage on the film formation surface by calculating the deposition as voxels imparted with status information indicating a bonded state or unbound state between the representative particles and the film formation surface.

A film formation device according to an embodiment of the present disclosure includes a film formation chamber, a control section, an optimization arithmetic section, and an output section. The control section controls operation of the film formation chamber. The optimization arithmetic section generates representative particles depending on an incident radical flux, and calculates adhesion, desorption, migration, and deposition of the respective representative particles to/from/on a film formation surface according to probability. The optimization arithmetic section searches for an optimization condition for a film formation process on the basis of a calculation result obtained thereby. The output section generates data necessary for the film formation condition of the film formation chamber to become the optimization condition found by the optimization arithmetic section and outputs the generated data to the control section. The optimization arithmetic section expresses film quality and film coverage on the film formation surface by calculating the deposition as voxels imparted with status information indicating a bonded state or unbound state between the representative particles and the film formation surface.

### BRIEF DESCRIPTION OF THE DRAWINGS

FIG. 1 is a diagram illustrating an example of processing procedure in a film formation simulation method according to an embodiment of the present disclosure.

FIG. 2 is a diagram illustrating a specific example of the processing procedure illustrated in FIG. 1.

FIG. 3 is a diagram illustrating a configuration example of a film formation simulator according to an embodiment of the present disclosure.

FIG. 4 is a diagram illustrating a concept of gas transport.

FIG. 5 is a diagram illustrating a concept of an actual film formation surface.

FIG. 6 is a diagram illustrating a concept incorporating the concept illustrated in FIG. 5 into a voxel model.

FIG. 7 is a diagram for describing generation of representative particles in a single voxel.

FIG. 8 is a diagram illustrating a concept of an actual film formation surface in migration.

FIG. 9 is a diagram illustrating a concept of a voxel model in migration.

FIG. 10 is a diagram illustrating an example of a cradle determination method in a voxel space.

FIG. 11 is a diagram illustrating an example of a cradle determination method in a voxel space.

FIG. 12 is a diagram illustrating an example of a cradle determination method in a voxel space.

FIG. 13 is a diagram for describing calculation of film density and permeability in a voxel space.

FIG. 14 is a diagram for describing calculation of adhesiveness in a voxel space.

FIG. 15 is a diagram for describing an annealing process in a voxel space.

FIG. 16 is a diagram for describing the annealing process in the voxel space.

FIG. 17 is a diagram for describing a blister in a voxel space.

FIG. 18 is a diagram for describing the blister in the voxel space.

FIG. 19 is a diagram for describing the blister in the voxel space.

FIG. 20 is a diagram for describing the blister in the voxel space.

FIG. 21 is a diagram illustrating a calculation result of coverage and film density distribution according to a CVD process.

FIG. 22 is a diagram illustrating results of a voxel bonded/unbound state distribution and gas flux distributions.

FIG. 23 is a diagram illustrating a calculation result of a permeability distribution.

FIG. 24 is a diagram illustrating a calculation result of an adhesiveness distribution.

FIG. 25 is a diagram illustrating a calculation result of a film density distribution after annealing.

FIG. 26 is a diagram illustrating a calculation result of an adhesiveness distribution after annealing.

FIG. 27 is a diagram illustrating a calculation result of a permeability distribution after annealing.

FIG. 28 is a diagram illustrating a concept of blister calculation.

FIG. 29 is a diagram illustrating trench crossover structure examples.

FIG. 30 is a diagram illustrating a modification of the processing procedure illustrated in FIG. 1.

FIG. 31 is a diagram illustrating a configuration example of a film formation simulation program according to an embodiment of the present disclosure.

FIG. 32 is a diagram illustrating a configuration example of a film formation device according to an embodiment of the present disclosure.

### MODES FOR CARRYING OUT THE INVENTION

Hereinafter, embodiments for practicing the present disclosure will be described in detail with reference to the drawings.

### Embodiment

### Outline

First, an outline of a film formation simulation method according to an embodiment of the present disclosure will be described. The film formation simulation method according to the present embodiment deals with a film formation method of forming a film including material particles by projecting the material particles to a surface to be processed (film formation surface).

Specifically, the film formation simulation method according to the present embodiment deals with various kinds of vapor deposition methods to predict film quality and film coverage of a film to be formed. For example, it is possible for the film formation simulation method according to the present embodiment to deal with film formation methods including physical vapor deposition (PVD) such as resistance heating deposition, electron beam evaporation, molecular-beam epitaxy, ion plating, or sputtering, and chemical vapor deposition (CVD) such as thermal CVD, plasma-enhanced CVD, atomic layer deposition (ALD), or metalorganic CVD.

Examples of the material particles include atoms, molecules, and ions obtained via ionization thereof. The material particles may be formed by using heat, plasma, or the like to resolve or ionize material gas introduced into a film formation chamber, or may be formed by collision of a metal target with noble gas atoms or the like. In addition, the material particles may be one kind or two or more kinds thereof. In other words, a film may be a film formed by a single kind of material, or may be a film formed by reacting a plurality of kinds of materials.

Examples of a film formation target includes a metal substrate, a semiconductor substrate, a glass substrate, a quartz substrate, a resin substrate, and the like. The shape and material of surfaces of the film formation target is not specifically limited. For example, a thin film or a fine structure may be formed on a surface of the film formation target. For example, the film formed on the film formation target may be a thin film having a film thickness of about several micrometers. In addition, it is possible for the film formation simulation method according to the present embodiment to deal with regions having a side length of about several micrometers, for example.

The film formation simulation method according to the present embodiment makes it possible to predict film quality and film coverage of a film to be formed according to the above-described film formation methods in the range of several tens nm.

### Flow pf Film Formation Simulation Method

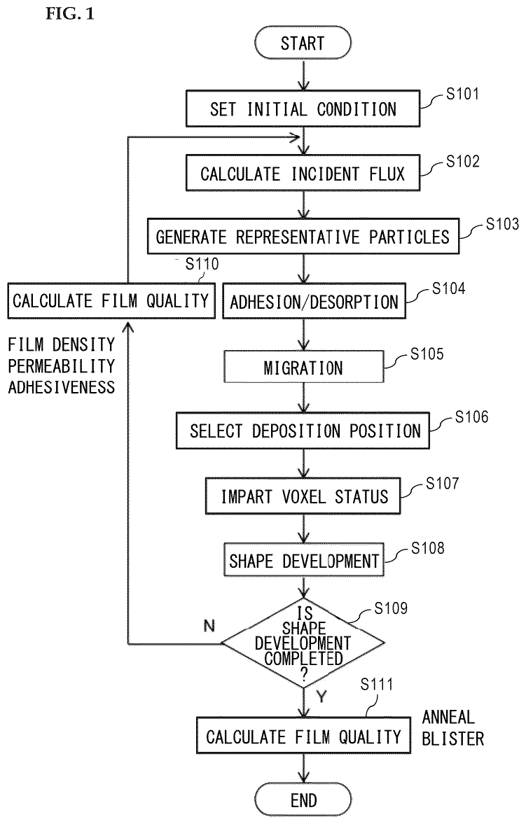

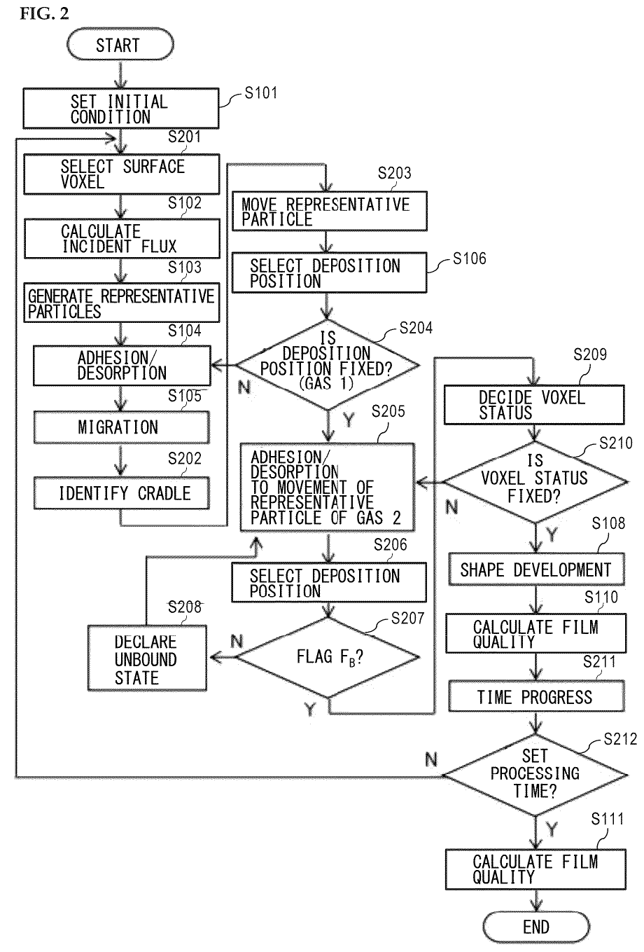

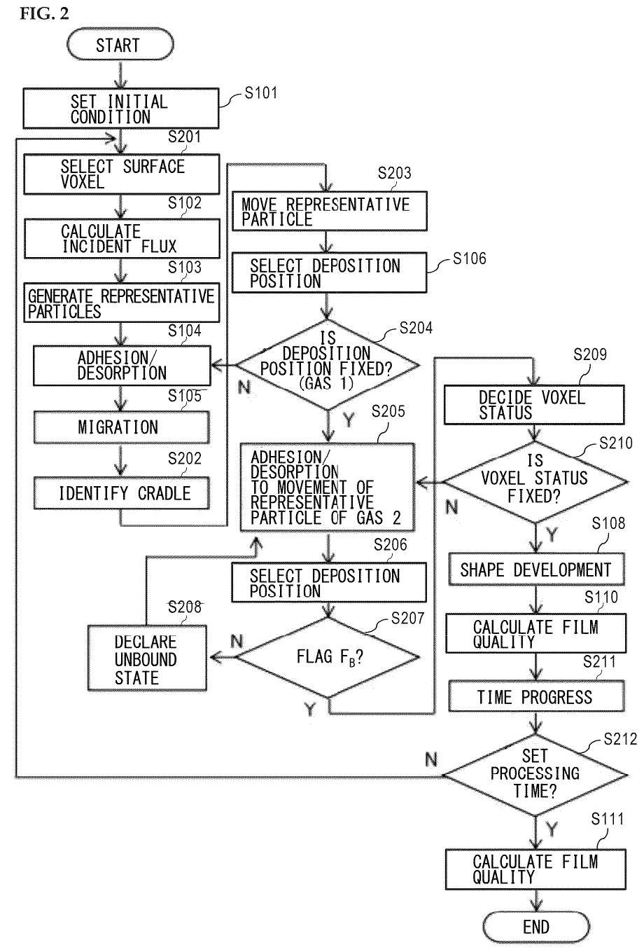

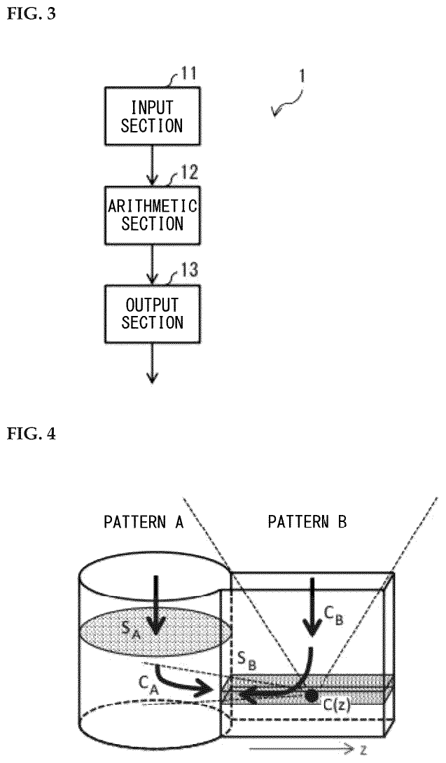

Next, an outline of a flow of the film formation simulation method according to the present embodiment will be described with reference to FIG. 1 and FIG. 2. FIG. 1 is a flowchart illustrating the outline of the flow of the film formation simulation method according to the present embodiment. FIG. 2 is a flowchart illustrating details of the flow of the film formation simulation method illustrated in FIG. 1. FIG. 3 is a diagram illustrating a configuration example of an information processing device (film formation simulator) for achieving the film formation simulation method.

### Configuration of Film Formation Simulator

A film formation simulator 1 illustrated in FIG. 3 includes an input section 11, an arithmetic section 12, and an output section 13. The input section 11 acquires film formation conditions for performing a predetermined film formation process on a film formation surface and inputs the acquired conditions to the arithmetic section 12. The input section 11 is implemented by a character-based user interface (CUI) or a graphical user interface (GUI) to set the film formation conditions. The arithmetic section 12 calculates film quality and shape development of the film formation surface through the simulation method illustrated in FIG. 1 and FIG. 2 (to be described later) on the basis of the film formation conditions input via the input section 11.

It is to be noted that, in the present embodiment, the arithmetic section 13 may be configured of hardware to achieve a calculation process which will be described later. However, a predetermined simulation program (software) may be used to execute the calculation process. In this case, the arithmetic section 13 may be configured, for example, of an arithmetic device such as a CPU (central processing unit), and the arithmetic section 13 may read the simulation program from outside and may execute the program, thereby performing calculation.

The simulation program may be stored, for example, in a database which is not illustrated, a memory section such as a ROM (read only memory) provided separately, etc. At this time, the simulation program may be implemented in advance, for example, in a component such as the database and the separately-provided memory section. Alternatively, the simulation program may be implemented from the outside, for example, into the component such as the database and the separately-provided memory section. It is to be noted that, in a case where the simulation program is acquired from the outside, the simulation program may be distributed from a medium such as an optical disk or a semiconductor memory, or alternatively, may be downloaded through a transmission means such as the Internet.

The output section 13 outputs an arithmetic result obtained by the arithmetic section 12 (a simulation result of the predetermined film formation process calculated by the arithmetic section 12). The output section 13 is implemented by a GUI to visualize the arithmetic result obtained by the arithmetic section 12 (the simulation result of the predetermined film formation process calculated by the arithmetic section 12). It is to be noted that, at this time, in addition to the simulation result of the film formation process, the output section 13 may output information such as parameters and film formation conditions used for the arithmetic, for example. The output section 13 may be configured, for example, of any of devices such as a display device unit that displays the simulation result, a printing device that prints out the simulation result, and a recording device that records the simulation result, or an appropriate combination thereof. It is to be noted that, although an example in which the simulator includes the output section 13 is described in the present embodiment, the present technique is not limited to this example and the output section 13 may be provided outside the simulator.

The simulator may further include a database section that stores various kinds of parameters necessary for the calculation process to be performed by the arithmetic section 12. Alternatively, such a database section may be provided outside the simulator. It is to be noted that the database section does not have to be provided in a case where the various kinds of parameters necessary for the calculation process is appropriately input from the outside.

### Details of Film Formation Simulation Method

In this simulation, a voxel model based on a flux method is used as a prediction technique of the film formation process. Generally, in the voxel model, voxels arranged in a calculation region are cubes. In the present embodiment, each voxel includes not only existence information indicating whether or not a film exists in there, but also information such as film coverage or film quality (for example, density, defect density, permeability, adhesiveness, and the like). In addition, in the present embodiment, a gas flux (incident flux) flowing into a voxel is calculated in view of not only a directly entering gas component (direct incident component) but also a gas component spreading through a surrounding pattern (spread gas component in response to surrounding structure). In addition, the existence of a film, coverage, and film quality are predicted by using a concept of representative particles depending on an incident radical flux. This makes it possible to predict the existence of a film, coverage, and film quality in the range of several tens nm with higher accuracy and lower cost than fluid calculation using Monte Carlo methods.

Next, the film formation simulation method illustrated in FIG. 1 and FIG. 2 will be described.

First, the arithmetic section 12 set an initial condition for film formation (Step S101 in FIG. 1 and FIG. 2). Specifically, the initial condition for film formation includes information related to the film formation condition, information related to a foundation layer, and other information For example, in a case where the film formation method is a vapor deposition method that uses gas as material, a model parameter related to surface reaction, an incident gas flux, ion incident energy/angle distribution, and the like may be set in Step S101 as the information related to the film formation condition. In addition, the shape and material of the foundation layer may be set as the information related to the foundation layer.

Next, the arithmetic section 12 selects surface voxels (Step S21 in FIG. 2). Voxels (air voxels) in an air region adjacent to voxels of a deposited film that has gotten deposited in a last time step are defined as the surface voxels. The surface voxels serve as targets of incident radical flux calculation and surface reaction calculation (adhesion, desorption, migration, and deposition).

Next, the arithmetic section 12 calculates an incident radical flux (Step S102 in FIG. 1 and FIG. 2). If ordinary fluid calculation is performed successively, huge calculation cost is necessary and it is not realistic to apply this to patterns on the order of nanometers to be used in semiconductor processes. Therefore, the arithmetic section 12 according to the present embodiment performs calculation while classifying gas into two types: gas components directly entering the surface voxels (direct incident components) and gas components spreading through a surrounding pattern (spread components).

Here, FIG. 4 illustrates a conceptual diagram of gas transport. A pattern A has a wider entrance than a pattern B. C_{B} represents a direct incident component (density). C_{B} relies on a solid angle obtained when the pattern entrance is viewed from a surface voxel. However, this includes no solid angle contribution of an adjacent pattern. C_{A} represents a spread component (density). The arithmetic section 12 calculates C_{A} by using the following expressions (1) to (3). By using a continuity equation (expression (1) and Bernoulli's principle (expressions (2) and (3)), it is possible to find the amount of gas flowing from the pattern A (with the large entrance) into the pattern B (with the small entrance) at a connection face.

$$[ Math . 1 ]$$

$${S}_{A} {V}_{A} = {S}_{B} {V}_{B} , V = \sqrt{\frac{8 {k}_{B} {T}_{N}}{π M}} \qquad ( 1 )$$

$$[ Math . 2 ]$$

$$\frac{1}{2} {{C}_{A} ( {V}_{A} )}^{2} {P}_{A} = \frac{1}{2} {{C}_{B} ( {V}_{B} )}^{2} {P}_{B} \qquad ( 2 )$$

$$[ Math . 3 ]$$

$${P}_{A} = {C}_{A} {k}_{B} T , {P}_{B} = {C}_{B} {k}_{B} T \qquad ( 3 )$$

Here, S_{A} represents an opening area of the pattern A. S_{B} represents an area of the connection face between the pattern A and the pattern B. V_{A} represents gas heat speed of the pattern A. V_{B} represents gas heat speed of the pattern B. V is a generic term for V_{A} and V_{B}. K_{B} represents a Boltzmann constant. T_{N} represents gas temperature. M represents the mass of gas. P_{A} represents pressure of a direct incident component. P_{B} represents pressure of a spread component.

In addition, the arithmetic section 12 calculates a contribution component C(z) of C_{A} to a corresponding voxel, according to the following expression (4). It is possible to approximately find C(z) according to the following expression (4) while approximately treating a region between the connection face SB and a black circle in the pattern B as a partial trench (region illustrated by a dot pattern). Here, W represents the width of the trench, and L represents a distance between the connection face and an opposite boundary of the pattern B. It is possible to calculate a total flux F in the corresponding voxel according to the following expression (5). The total flux F corresponds to the incident radical flux in the corresponding voxel. In a case where there is a plurality of patterns (hereinafter, referred to as “surrounding patterns”) around the pattern B, it is possible to weight C(z) by multiplying C(z) of the respective surrounding patterns by 1/L, add the obtained weighted values (C(z)×1/L), and thereby find a total flux F in the corresponding voxel.

$$[ Math . 4 ]$$

$$[ Math . 5 ]$$

$$F = {C}_{B} {V}_{B} + C ( z ) {V}_{A} \qquad ( 5 )$$

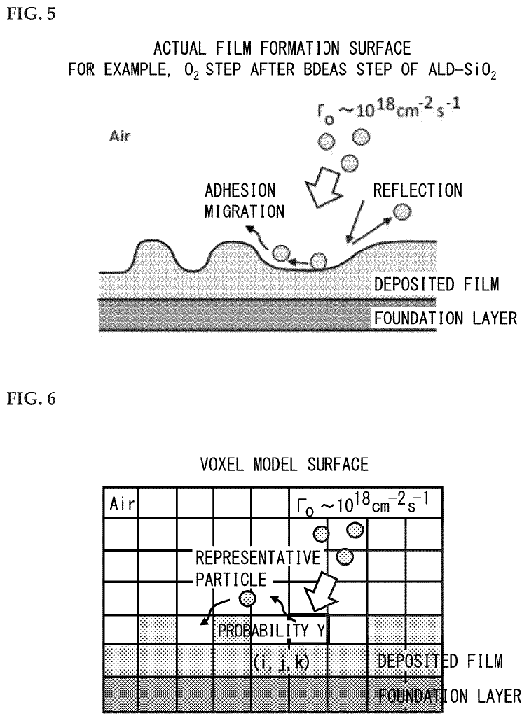

Next, the arithmetic section 12 generates representative particles depending on the incident radical flux (=the total flux) (Step S103 in FIG. 1 and FIG. 2). FIG. 4 illustrates a conceptual diagram of an actual film formation surface (for example, O₂ step after BDEAS step of ALD-SiO₂). FIG. 6 illustrates a conceptual diagram incorporating the conceptual diagram illustrated in FIG. 5 into a voxel model.

On an actual surface, a film is formed through repetition of adhesion, migration and deposition while each incident particle bonds with a surface particle and this causes potential change. To drastically reduce calculation load, an algorithm according to the present embodiment treats the plurality of incident particles as a single representative particle. This makes it easy to deal with a radical flux of 10¹⁸[/cm²/S] or less, and deal with adhesion, desorption, migration, and deposition of the representative particle according to probability. This is application of a so-called statistical ensemble method.

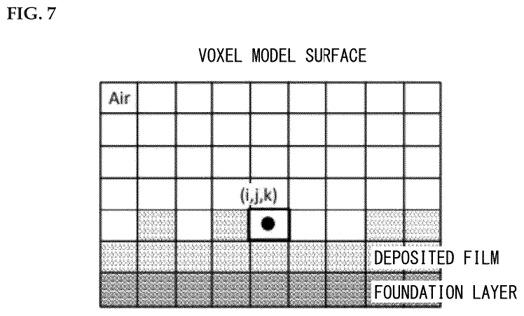

The arithmetic section 12 calculates the number N of representative particles to be generated for each voxel. The number N of representative particles to be generated is calculated (see expression (6)) by setting tentative density ρ [particles/cm³] of the deposited film and dividing the number of radical particles (F×L²×10⁻¹⁴×dt [particles]) entering a single voxel (for example, a voxel surrounded by a thick frame in FIG. 7) having a volume of L³×10²¹ [cm³] by the number of particles (ρ×L³×10⁻²¹ [particles]) in a single voxel of the deposited film. The number N of representative particles to be generated varies depending on the incident radical fluxes F [fluxes/cm²/s] in the pattern.

$$[ Math . 6 ]$$

$$N = F \times {L}^{2} \times {10}^{- 14} dt / ( ρ \times {L}^{3} \times {10}^{- 21} ) \qquad ( 6 )$$

For example, the number N of representative particles to be generated becomes 20 when F=10¹⁸ [fluxes/cm²/s], dt=0.1 [s], L=5 [nm], and ρ=10²² [particles/cm³]. In a case where a plurality of types of radical particles exists, the arithmetic section 12 performs such a calculation for each type of radical particles. In a case of forming a film through the CVD or PVD, the arithmetic section 12 calculates the number N of representative particles to be generated for each type of gas in a same time step. In a case of forming a film through the ALD, the arithmetic section 12 calculates the number N of representative particles to be generated for each type of gas in different time steps.

Next, the arithmetic section 12 decides about adhesion/desorption of the respective representative particles (Step S104 in FIG. 1 and FIG. 2). Specifically, the arithmetic section 12 decides, by using random numbers, whether the respective representative particles adhere with an adhesion probability Y(0≤Y≤1) or desorb with probability (1-Y). In a case where the representative particle is in contact with the foundation layer (very early stage of film formation), influence of variation of an adhesion probability Ys depending on foundation damage Da caused by processing is taken into consideration (expression (7)). Meanwhile, an adhesion probability Yd stays constant on the deposited film (expression (8)). It is to be noted that a, b, and c represent constants set by a user. Da is imparted with an experimental value or result calculated by another film formation simulator. Further surface reaction is not calculated in a case where it is determined as desorption.

$$[ Math . 7 ]$$

$${Y}_{S} = a + b \times {D}_{a} \qquad ( 7 )$$

$$[ Math . 8 ]$$

$${Y}_{d} = c \qquad ( 8 )$$

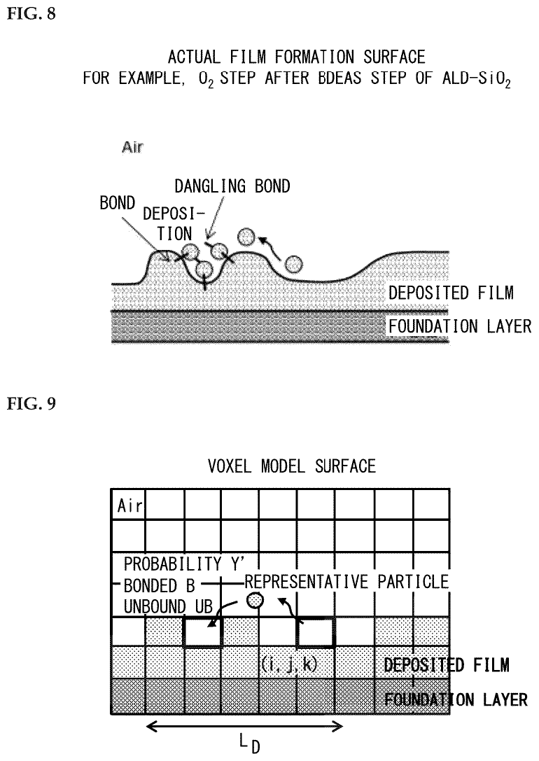

Next, the arithmetic section 12 decides about a migration range (Step S105 in FIG. 1 and FIG. 2). FIG. 8 illustrates a conceptual diagram of an actual film formation surface in migration and deposition. FIG. 9 illustrates a conceptual diagram of a voxel model in migration and deposition.

The radical particles that have adhered using energy of substrate temperature migrate on a surface. In a region with stable surface potential, the radical particles bond with the deposited film (film formation surface) to deposit a film. At this time, some of the radical particles may have a dangling bond (see FIG. 8). When simulating this phenomenon into a voxel model, the followings are taken into consideration.

First, a 2L_{D} cubic range (migration range) of a migration length L_{D} (expression (9)) calculated depending on substrate temperature T and activation energy Ed is decided (Step S105 in FIG. 1 and FIG. 2). Next, a cradle (recess with small radius of curvature) is searched for in the 2L_{D} cubic range (FIG. 9). Here, D₀ represents a diffusion constant, τ represents a time constant, and K_{B} represents a Boltzmann constant. √D_{0τ} and Ed in a right-hand side of the expression (9) are parameters to decide a value on the basis of first principle calculation or a correlation (slope: Ed, and intercept: √D_{0τ}) between actually measured substrate temperature and actually measured film density.

$$[ Math . 9 ]$$

$${L}_{D} = \sqrt{{D}_{0} τ} \times {e}^{- Ed / 2 {K}_{B} T} \qquad ( 9 )$$

The following expression (10) represents surface potential μ by using a radius of curvature 1/R. The radical particles migrate in such a manner that the surface potential μ gets minimized, that is, in such a manner that a structure (cradle) with the small radius of curvature 1/R is gone. Here, μ₀ represents chemical potential on a flat film, γ represents surface tension, Ω represents atomic volume, and 1/R represents the radius of curvature.

$$[ Math . 10 ]$$

$$μ = {μ}_{0} + \frac{γ}{R} Ω \qquad ( 10 )$$

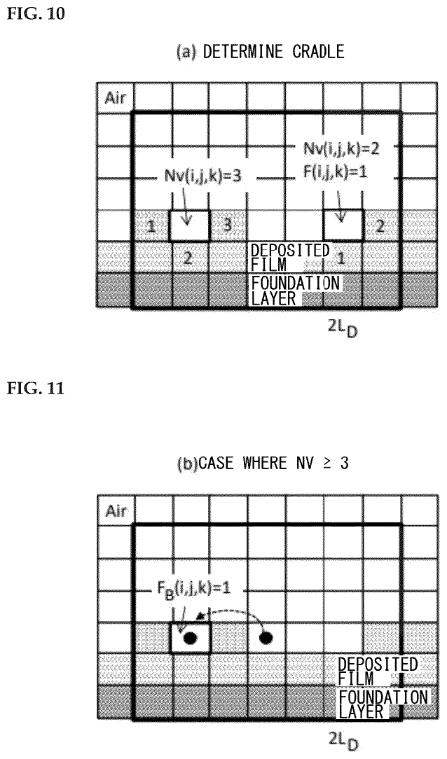

Next, the arithmetic section 12 identifies the cradle in a voxel space (Step S202 in FIG. 2). Specifically, when focusing on an air voxel (barycentric coordinates: (i,j,k)) in contact with the deposited film in the migration range (2L_{D}) surrounded by a thick frame as illustrated in FIG. 10, material of top, bottom, left, and right voxels adjacent to the focused air voxel are determined. In a case where a voxel adjacent to the focused air voxel corresponds to the deposited film, 1 is added to a determination index Nv(i,j,k) of the focused air voxel. The focused air voxel is determined as follows on the basis of the value of the determination index Nv.
In a case where Nv≥3, it is determined that the focused air voxel is the cradle.
   In a case where Nv=1 or 2, it is determined that the focused air voxel is not the cradle. It is assumed that a flag: F(i,j,k)=1.
   In a case where Nv=0, it is determined that the focused air voxel remains as air.

For example, it is assumed that one air voxel with Nv=2 and another air voxel with Nv=3 among the two air voxels, each of which is surrounded by a thick frame in FIG. 10. At this time, it is determined that the air voxel with Nv=2 is not a cradle, and it is determined that the air voxel with Nv=3 is a cradle.

Next, the arithmetic section 12 moves a representative particle (Step S203 in FIG. 2). Specifically, if an air voxel with Nv≥3 exists in a migration range, the representative particle (gas 1, for example, BDEAS in ALD-SiO₂ process) migrates to the air voxel with Nv≥3, and a flag F_{B}(i,j,k) of the voxel to determine its bonding status is set to 1. In a case where a plurality of cradles exists in the migration range, F_{B}(i,j,k) of a cradle closest to the representative particle is set to 1 (FIG. 11).

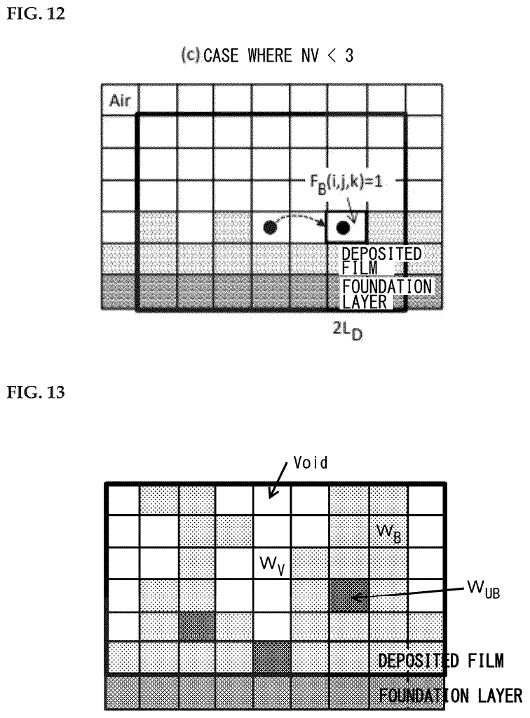

Meanwhile, in a case where the air voxel with Nv≥3 does not exist in the migration range, a migration destination voxel of the representative particle is decided from among voxels with F(i,j,k)=1 by using random numbers (according to probability) A flag F_{B}(i,j,k) of the migration destination voxel to determine its bonding status is set to 1 (FIG. 12). As described above, the arithmetic section 12 selects (decides) a deposition position of a representative particle (Step S106 in FIG. 1 and FIG. 2).

The arithmetic section 12 executes the above-described Steps S104 to 106 with regard to all generated representative particles (N in Step S204) until the deposition position is fixed.

It is to be noted that, in a case of forming a film by using a plurality of types of gas (for example, gas 1 and gas 2), the arithmetic section 12 selects (decides) a deposition position of a representative particle of the gas 1 (for example, BDEAS), and then performs adhesion/desorption to movement, deposition position selection (decision) (Steps S205 and S206) with regard to a representative particle of the gas 2 (for example, O₂), for example. In other words, the film is formed through the ALD. At this time, with regard to a voxel whose F_{B}(i,j,k) has already been set to 1 by the gas 1 (Y in Step S207), the arithmetic section 12 uses random numbers to decide whether its status obtained at the time of deposition is a bonded state (probability Y_{B}) or an unbound state (dangling bond: probability (1-Y_{B})). Meanwhile, with regard to a voxel with F_{B}(i,j,k)=0, the arithmetic section 12 determines that its status obtained at the time of deposition is the unbound state (Step S208). It is to be noted that, if, when deciding a status of a voxel, ions enter the voxel (that is, incident ion flux Γᵢ exists), the arithmetic section 12 determines influence of bonding enhancement by the ions (determines whether the status is the bonded state or the unbound state) on the basis of the flux and energy of the incident ions.

Here, a detailed calculation method will be described. In other words, the following expression (11) represents the number of ions entering a migration destination voxel (voxel size: L) within a time step dt. By using the expression (11) and an ion energy distribution function (IEDF), it is possible to calculate total incidence energy Eₜₒₜ into the voxel. Meanwhile, by using the tentative density p of the deposited film, the number of bonds in a single voxel becomes ρ×L³−1. Therefore, energy represented by the following expression (12) is added per bond.

$$[ Math . 11 ]$$

$${Γ}_{i} ( I , J , K ) \times {L}^{2} \times dt \qquad ( 11 )$$

$$[ Math . 12 ]$$

$${Γ}_{i} ( I , J , K ) \times {L}^{2} \times dt / ( ρ \times {L}_{3} - 1 ) \qquad ( 12 )$$

The representative particle is deposited in the bonded state with the probability Y_{B}, in a case where the energy found as described above is larger than bond energy E_{B} (value set by user) between atoms in the deposited film. Meanwhile, the representative particle is deposited in the bonded state with the probability Y_{B}′ (value set by user), in a case where the energy found as described above is smaller than the bond energy E_{B} (value set by user) between atoms in the deposited film. As described above, the arithmetic section 12 decides the film status (bonded state or unbound state) of a voxel (Step S209). In other words, the deposition is calculated as voxels imparted with the bonded state or unbound state between the representative particles and the film formation surface.

The arithmetic section 12 executes the above-described Steps S205 to S209 (N in Step S210) until the film statuses (bonded state or unbound state) of the all voxels in the migration range are decided. The arithmetic section 12 performs the shape development in a case where the film statuses (bonded state or unbound state) of the all voxels in the migration range are decided (Y in Step S210). Specifically, the arithmetic section 12 recognizes a voxel whose film status is the bonded state as the deposited film, and a voxel whose film status is the unbound state as an unbound film (defective film). In such a way, a film is stacked and its shape changes in each time step.

Next, the arithmetic section 12 calculates film quality (Step S110 in FIG. 1 and FIG. 2). As the film quality, film density, permeability, and adhesiveness distributions are calculated. With regard to film morphology illustrated in FIG. 12, the film density, permeability, and adhesiveness distributions are calculated as physical quantities averaged in a set range indicated by a thick frame, by using information imparted to each voxel. The information indicates the bonded state (B), the unbound state (UB), or a void region. In other words, the film quality and film coverage on the film formation surface is expressed by calculating the deposition as voxels imparted with status information indicating a bonded state or unbound state between the representative particles and the film formation surface. The setting range is a parameter set by the user. For example, the set range is 100 nm.

### Film Density

In the set range illustrated in FIG. 13, the arithmetic section 12 gives density weight W of each voxel, and define a sum-total average thereof as local film density DL(l,m,n) (expression (13)). A density weight W of a bonded voxel is W_{B}, a density weight W of an unbound voxel is W_{UB}, and a density weight W of a voxel in the void region is W_{V}. It is to be noted that (l,m,n) represents barycentric coordinates of the set region, and Q represents the number of voxels in the set region. However, D_{L0} is found through actual measurement under typical process conditions, or is found through the MD calculation or the like. D_{L0} is a parameter input by the user.

$$[ Math . 13 ]$$

$${D}_{L} ( l , m , n ) = {D}_{L 0} {\sum }_{i = \{ B , U , B , V \}} {W}_{i} / Q \qquad ( 13 )$$

### Permeability

The arithmetic section 12 calculates a ratio between volume V_{y} of the void region in the set region illustrated in FIG. 13 and volume Vₜₒₜ of the set region illustrated in FIG. 13, as (index of) permeability WP (expression (14)). It is to be noted that (l,m,n) represents barycentric coordinates of the set region.

$$[ Math . 14 ]$$

$$WP ( l , m , n ) = {V}_{v} / {V}_{tot} \qquad ( 14 )$$

### Adhesiveness

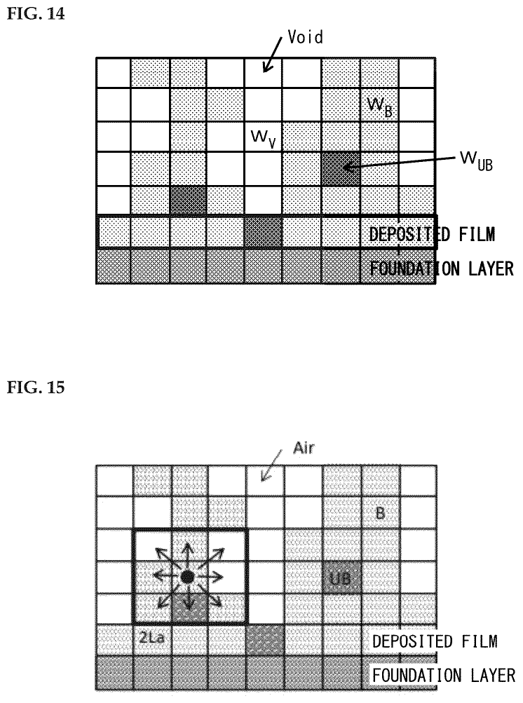

As illustrated in FIG. 14, the arithmetic section 12 treats voxels in contact with the foundation layer as targets and calculates a ratio between volume V_{UB} of the unbound voxels (UB) in the set region illustrated in FIG. 14 and volume Vₜₒₜ of the set region illustrated in FIG. 14, as (index of) adhesiveness Ad (expression (15)). (l,m,n) represents barycentric coordinates of the set region.

$$[ Math . 15 ]$$

$$Ad ( l , m , n ) = {V}_{UB} / {V}_{tot} \qquad ( 15 )$$

After the above-described film quality calculation, the arithmetic section 12 pushes a clock during calculation forward by the time step dt (Step S211). Next, in a case where calculation time does not reach predetermined processing time (N in Step S212), the arithmetic section 12 continues executing the above-described Step S201 and following steps. Meanwhile, in a case where the calculation time reaches the predetermined processing time (Y in Step S212), the arithmetic section 12 ends the film formation process and then calculates film quality of an annealing process (Step S111).

### Annealing Calculation

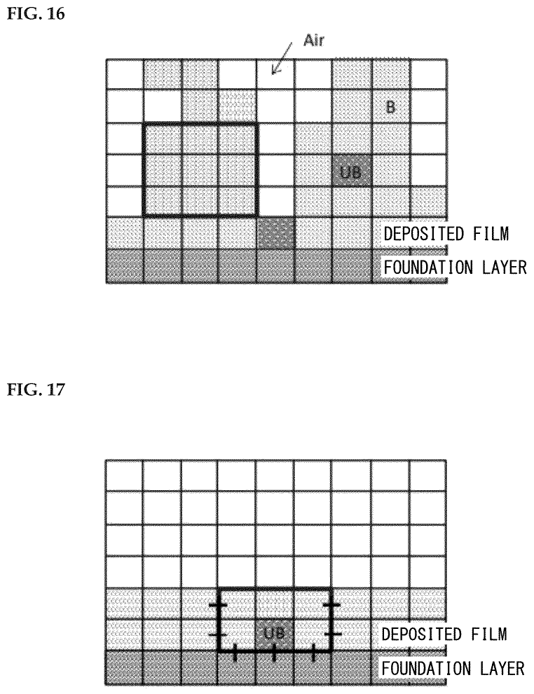

Here, the arithmetic section 12 calculates thermal denaturation of a film caused by annealing, that is, film density to be obtained after annealing. FIG. 15 illustrates a conceptual diagram of change in density and film morphology caused by the annealing. First, the arithmetic section 12 calculates a diffusion length La depending on the substrate temperature T, and equipartitions density ρ(I,J,K) into Na number of voxels in a range 2La surrounded by a thick frame in FIG. 15. The voxels include air voxels. As illustrated in FIG. 16, this makes it possible to diffuse representative particles from a voxel indicated by a black circle in FIG. 15 to other voxels in the range 2La surrounded by the thick frame in FIG. 15. It is to be noted that the same expression as the expression (8) is used for calculating the diffusion length La. However, the parameter value in the expression (8) is different from the parameter value used for calculating the migration length LD.

Moreover, density ρₐ after the annealing may be indicated as follows in consideration of representative particles that simultaneously flow in from surrounding voxels (I′,J′,K′).

$$[ Math . 16 ]$$

$${ρ}_{a} ( i , j , k ) = \frac{ρ ( i , j , k )}{( {N}_{a} )} + {\sum }_{\{ 2 {L}_{a} \}} \frac{ρ ( {i}^{′} , {j}^{′} , {k}^{′} )}{( {N}_{a} )} \qquad ( 16 )$$

$$[ Math . 17 ]$$

$${N}_{a} = {[ int ( \frac{2 {L}_{a}}{L} ) ]}^{3} \qquad ( 17 )$$

In addition, to reflect an improvement in crystallinity of the deposited film by heat, ρₐ in the following expression (18) is multiplied by a correction term β depending on the substrate temperature T. Here, A represents a coefficient, Eₐ represents activation energy, and K_{B} represents a Boltzmann constant.

$$[ Math . 18 ]$$

$$β = A \times {e}^{- Ea / 2 {K}_{B} T} \qquad ( 18 )$$

After the above calculation, the status of the voxel UB (unbound state) is changed into the voxel B (bonded state) in a case where the voxel UB has higher density than the density of the voxel B (bonded state) before the annealing. In addition, in a case where an air voxel has higher density than a set density threshold (set by user), the state of the air voxel is changed into a deposited film voxel and a similar process is applied thereto. Such a calculation is performed on every voxel except foundation voxels.

### Blister Calculation

As calculation of a blister (film peeling) to be caused immediately after completion of the film formation process or immediately after the annealing (at the time of annealing), the arithmetic section 12 performs a voxel movement process (to be described below) on voxels UB (unbound state) in the deposited film.

First, gas density np that is a blister factor in the UB is calculated. A flux F_{B} of factor gas (hydrogen (H) in SiO₂ film formation) is also derived when calculating fluxes of the gas 1 and gas 2 in the film formation calculation, and the derived flux F_{B} is stored in a voxel. The following expression (19) represents the gas density n_{B} by using the F_{B}, the voxel size L, film formation time t, and the number NS of super-particles.

$$[ Math . 19 ]$$

$${n}_{B} = {F}_{B} / L \times t / {N}_{S} \qquad ( 19 )$$

The following expression (20) represents energy of gas pressure to be obtained on an assumption that a portion (R_{B}≤1 and depending on incident ion energy) of the gas density np obtained by using the expression (19) exits from a voxel as degassing.

$$[ Math . 20 ]$$

$${P}_{B} ( {L}^{3} ) = {R}_{B} {n}_{B} \times {k}_{B} \times T \times {L}^{3} \qquad ( 20 )$$

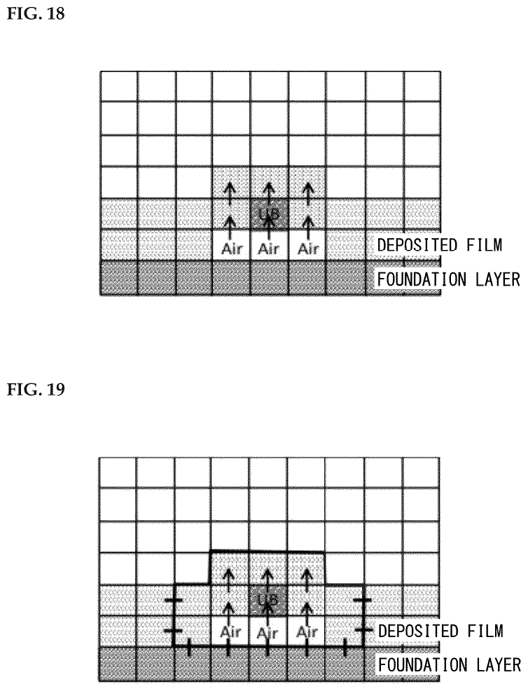

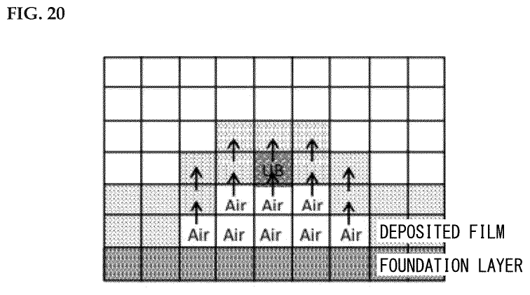

Here, T represents substrate temperature in film formation. In a case where P_{B}(L³) is compared with a sum-total E_{Btot} of bond energy of a voxel adjacent face indicated by thick solid lines across a thick frame in FIG. 17 and this result indicates that P_{B}(L³) is larger than the sum-total E_{Btot}, every voxel in the thick frame in FIG. 17 moves up by one voxel, and voxels at the original positions become air voxels (FIG. 18). In addition, in a case where P_{B}(L³) is compared with a sum-total E_{Btot} of bond energy of a voxel adjacent face indicated by thick solid lines across a thick frame in FIG. 19 (thick frame that surrounds voxels adjacent to the outside of the thick frame in FIG. 17) and this result indicates that P_{B}(L³) is larger than the sum-total E_{Btot}, every voxel in the thick frame in FIG. 19 moves up by one voxel, and voxels at the original positions become air voxels (FIG. 20). Such a procel is repeatedly executed until the sum-total E_{Btot} exceeds P_{B}(L³). In a case where a plurality of air regions induced by UB overlaps each other, it is determined which region has a larger size in a way similar to the above-described way with regard to a region including the plurality of air regions that overlaps each other.

It is to be noted that the following expression approximately represents the sum-total E_{Btot} by using area density σ of adjacent voxels and average bond energy E_{B}. In addition, to reflect an influence of ions to bond formation during film deposition, a value multiplied by a correction term (exp(−E₀/E)×2.718) relying on ion energy E is used as R_{B}. Here, E₀ represents criterial ion energy.

$$[ Math . 21 ]$$

$${E}_{Btot} \sim {\sum }_{\{ Neiborhood \}} ( σ {L}^{2} \times {E}_{B} ) \qquad ( 21 )$$

### Effects

The film formation simulation method and the film formation simulator 1 according to the present embodiment generate representative particles depending on an incident radical flux, and calculate adhesion, desorption, migration, and deposition of the respective representative particles to/from/on a film formation surface according to probability. This makes the accuracy and calculation time independent of the number of particles. In addition, according to the present embodiment, through the calculation, it is possible to expresses film quality and film coverage on the film formation surface by calculating the deposition as voxels imparted with status information indicating the bonded state or unbound state between the representative particles and the film formation surface. Accordingly, a database relying on morphology and a gas flux does not have to be separately prepared to calculate the film quality. This makes it possible to shorten the calculation time and improve the calculation accuracy. In addition, it is also expected to shorten turnaround time (TAT) before utilization of the algorithm according to the present embodiment.

According to the present embodiment, it is possible to calculate the incident radical flux on the basis of the gas component and the spread gas component. The gas component directly enters a voxel of the film formation surface, and the spread gas component enters a voxel of the film formation surface in response to a surrounding structure. This makes it possible to improve the calculation accuracy reflecting real structures.

According to the present embodiment, it is possible to determine whether the representative particles and the film formation surface are bonded or unbound, on the basis of energy and a flux of ions entering the voxel of the film formation surface. This makes it possible to achieve the film formation process that takes into consideration the influence of bonding enhancement by the ions.

According to the present embodiment, it is possible to calculate film density, permeability, and adhesiveness to the film formation surface by using the status information indicating the bonded state or unbound state. This makes it possible to achieve the film formation process with higher accuracy.

According to the present embodiment, it is possible to calculate the number of representative particles generated by type of gas in a same time step, in a case of forming a film by using a plurality of types of gas. This expresses the film formation process using the CVD or PVD.

According to the present embodiment, it is possible to calculate the number of representative particles generated by type of gas in different time steps, in a case of forming a film by using a plurality of types of gas. This expresses the film formation process using the ALD.

According to the present embodiment, it is possible to calculate a blister, film density, or both at a time of annealing after film formation. As described above, according to the present embodiment, it is possible to express not only the film formation process but also change in film caused by the annealing.

The film formation simulator 1 according to the present embodiment includes the input section 11 and the output section 143, the input section 11 being implemented by a CUI or a GUI to set the film formation conditions, the output section 13 being implemented by a GUI to visualize the arithmetic result obtained by the arithmetic section 12. This allows the user to operate the film formation simulator in a relatively simple way, and to recognize the arithmetic result obtained by the film formation simulator 1 in a relatively simple way.

### EXAMPLE 1

### Basic CVD Calculation (Coverage+Film Density)

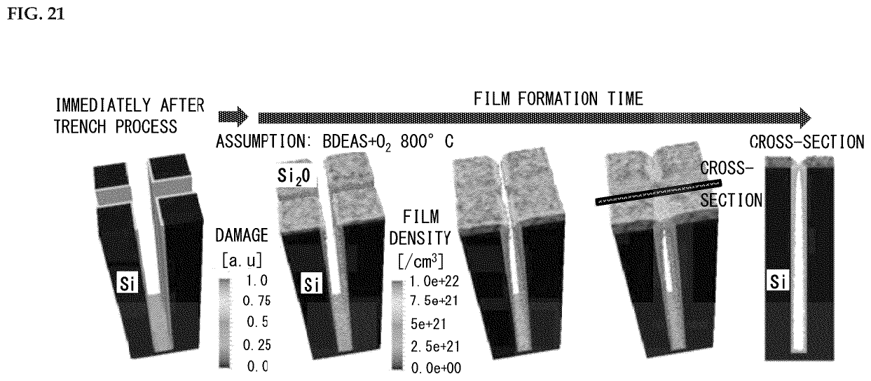

FIG. 21 illustrates calculation of coverage and film density distribution according to the CVD process in the present Example. In this Example, substrate temperature is set to 800° C., gas pressure is set to 400 Pa, and a film is formed in a foundation Si trench by using BDEAS BDEAS+O₂ gas. The foundation Si trench has a structure including two intersecting trenches with a linewidth of 150 nm, a depth of 2 μm, and a length of 450 nm. FIG. 21 illustrates a simulation result that takes into consideration an adhesion probability (0.5+0.5×Da) reflecting processing damage caused during trench etching and a voxel bonded state probability (0.2 in a case where no ion enters, but 1 in a case where the ion enters) during deposition caused by incident ions (energy of up to 50 eV). The activation energy (determination of bonded state by ion incident and migration) is uniformly set to 0.4 eV. The voxel size is set to 5 nm. The set range of averaging to be used for calculating the film quality is set to 25 nm. In addition, the incident ion flux into a pattern is set to 4×10¹⁶/cm²/s, and the radical flux (BDEAS, O2) is set to 1×10¹⁸/cm²/s.

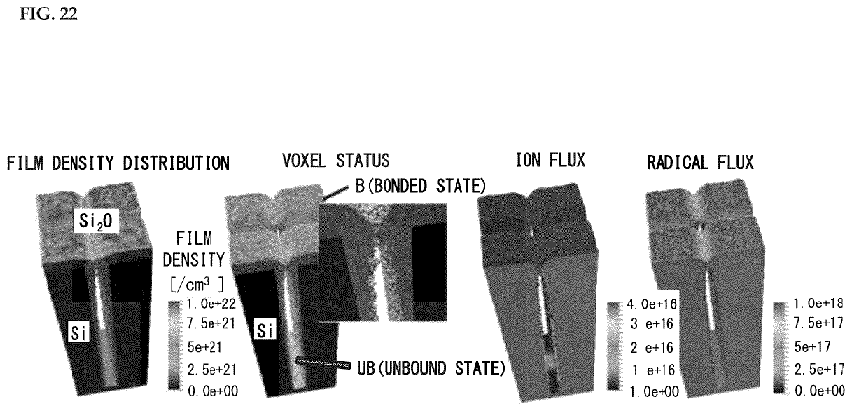

As the film formation time advances, a slit region of the trench gets sealed, SiO₂ is thinly stacked in the trench, and a void is formed. In addition, high film density is obtained in a flat part that is enormously influenced by ion irradiation (there is a high possibility that the voxel is determined as the bonded state), and low film density is obtained within the trench that is less influenced by the ion irradiation. FIG. 22 illustrates both results of a voxel bonded/unbound state distribution and gas flux distributions.

### EXAMPLE 2

### Basic CVD Calculation (Permeability)

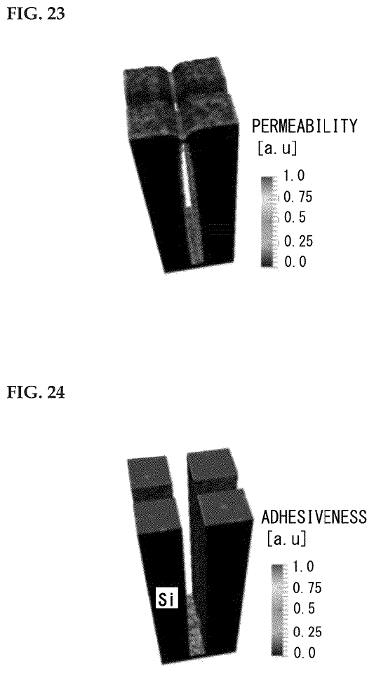

FIG. 23 illustrates a calculation result of permeability distribution in this Example. This is the calculation result obtained by using the foundation structure and film formation conditions according to Example 1. Low permeability is obtained in the flat part, and high permeability is obtained within the trench.

### EXAMPLE 3

### Basic CVD Calculation (Adhesiveness)

FIG. 24 illustrates a calculation result of adhesiveness distribution in this Example. This is the calculation result obtained by using the foundation structure and film formation conditions according to Example 1. Strong adhesiveness is obtained in the flat part, and weak adhesiveness is obtained within the trench.

### EXAMPLE 4

### Basic CVD Calculation (Annealing)

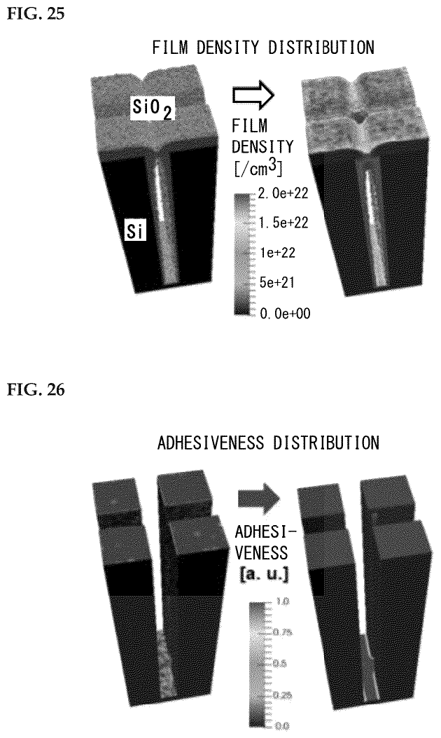

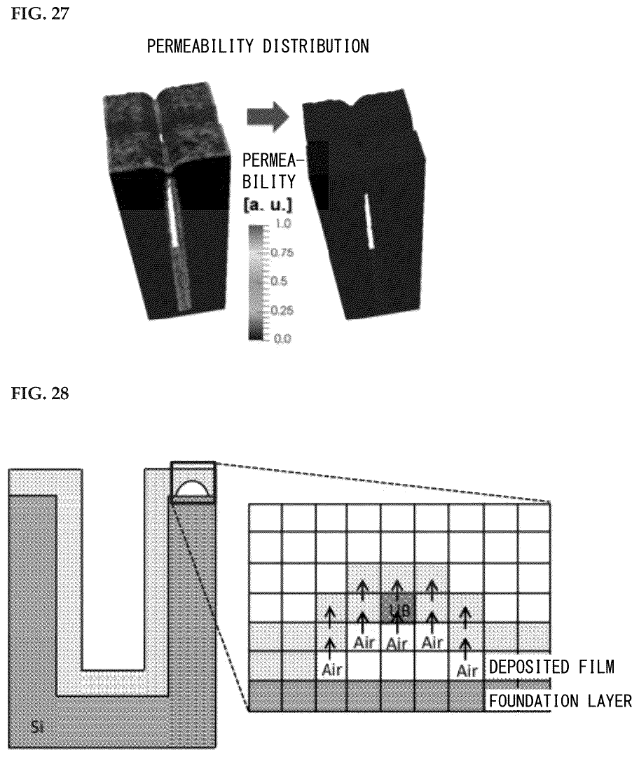

FIG. 25, FIG. 26, and FIG. 27 illustrate results of annealing calculation in this Example. These calculation results show changes in film density distribution (FIG. 25), adhesiveness distribution (FIG. 26), and permeability distribution (FIG. 27) when annealing is performed at 1000° C. after the film formation according to Example 1, and these calculation results show that such film qualities get improved toward the inside of the trench.

### EXAMPLE 5

### Basic CVD Calculation (Blister)

FIG. 28 illustrates a conceptual diagram of blister calculation in this Example. The blister calculation is performed after the film formation according to Example 1. A blister (film peeling) having a size corresponding to two layers of voxels is formed on the flat part on an assumption that the substrate temperature is set to 800° C., a factor gas flux is set to 1×10¹⁸/cm²/s, R_{B} is set to 0.01, the bond energy is set to 5 eV.

### EXAMPLE 6

### Applied CVD Calculation (Pattern With Wide Linewidth+Pattern With Narrow Linewidth)

In Example 1, calculation is performed on the assumption that there is a structure in which two trenches with a same linewidth intersect each other. Meanwhile, calculation using an algorithm according to Example 6 is not limited thereto. The algorithm according to Example 6 is applicable to any structure including a mixture of a pattern with a wide linewidth and a pattern with a narrow linewidth.

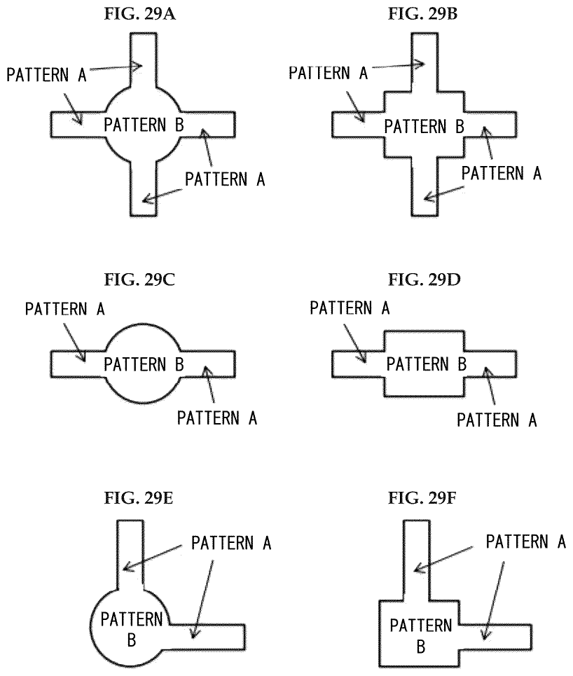

For example, as illustrated in FIG. 29(A), it is possible to perform calculation using the algorithm according to Example 6 with regard to a pattern including a circular pattern B and four rectangular patterns A that are coupled to a perimeter of the pattern B. In addition, for example, as illustrated in FIG. 29(B), it is possible to perform calculation using the algorithm according to Example 6 with regard to a pattern including a rectangular pattern B and four rectangular patterns A that are coupled to a perimeter of the pattern B.

In addition, for example, as illustrated in FIG. 29(C), it is possible to perform calculation using the algorithm according to Example 6 with regard to a pattern including a circular pattern B and two rectangular patterns A that are coupled to a perimeter of the pattern B at opposing positions across the circular pattern B. In addition, for example, as illustrated in FIG. 29(D), it is possible to perform calculation using the algorithm according to Example 6 with regard to a pattern including a rectangular pattern B and two rectangular patterns A that are coupled to a perimeter of the pattern B at opposing positions across the rectangular pattern B.

In addition, for example, as illustrated in FIG. 29(E), it is possible to perform calculation using the algorithm according to Example 6 with regard to a pattern including a circular pattern B and two rectangular patterns A that are coupled to a perimeter of the pattern B at positions where their extending directions intersect at a 90-degree angle. In addition, for example, as illustrated in FIG. 29(F), it is possible to perform calculation using the algorithm according to Example 6 with regard to a pattern including a rectangular pattern B and two rectangular patterns A that are coupled to a perimeter of the pattern B at positions where their extending directions intersect at a 90-degree angle.

### EXAMPLE 7

### ALD Calculation

The above Examples 1 to 6 has described the CVD calculation. Meanwhile, according to Example 7, it is possible to calculate the coverage and film quality as an ALD process by alternately repeating the calculations regarding the gas 1 and gas 2 in FIG. 2 at set time intervals (for example, every ten seconds) until film formation end time.

### EXAMPLE 8

### PVD Calculation

The above Examples 1 to 6 has described the CVD calculation. Meanwhile, according to Example 8, it is possible to perform PVD calculation on a metal film target including a single element by calculating only the gas 1 in FIG. 2. Alternatively, it is possible to perform the PVD calculation on a compound target including a plurality of elements by calculating gas 3 and more in addition to the gas 1 and the gas 2.

### EXAMPLE 9

### Collaboration With Gas-Phase Calculation

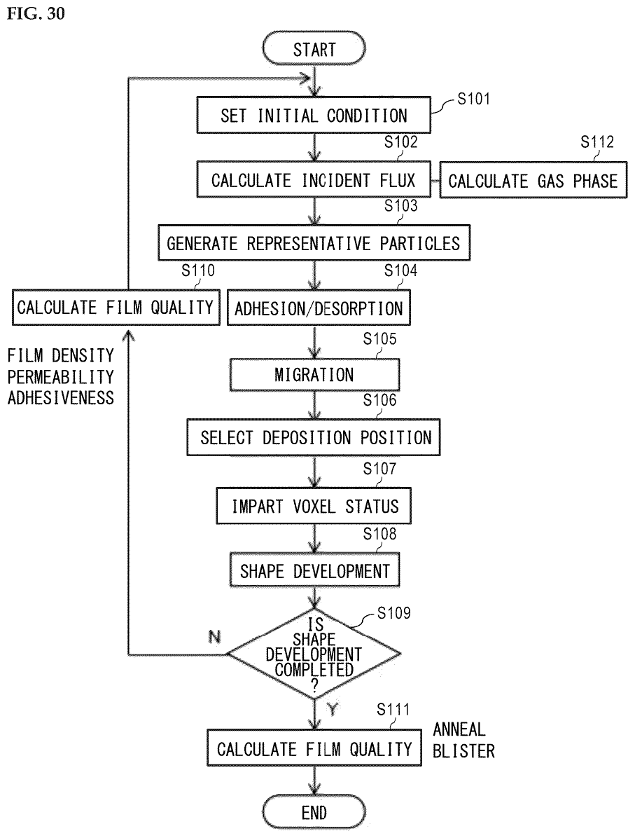

FIG. 30 illustrates Example 9. By performing the gas-phase calculation with regard to the incident flux calculation in FIG. 1, it is possible to simulate density distributions of the gas 1 and gas 2 in a chamber plane. By inputting these density distributions and multiplying gas heat speeds, a flux is derived. In the gas-phase calculation, power to be applied to an upper electrode, frequency, gas species, gas flow rate, gas pressure, chamber wall status (gas adhesion probability), chamber configuration, exhaust velocity are input. Alternatively, interpolation calculation based on an actual measurement database or calculation using machine learning (for example, Gaussian process regression, deep learning, etc., but the method is not limited) may be used.

### EXAMPLE 10

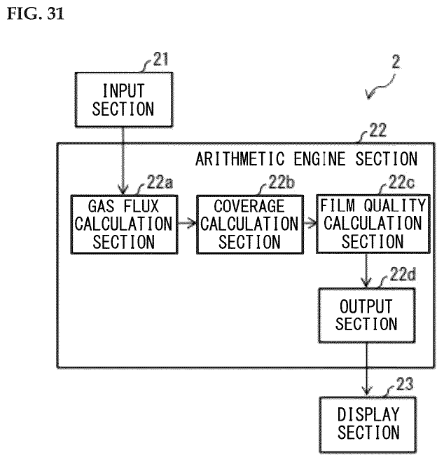

FIG. 31 illustrates a configuration example of information processing software (film formation simulation program) for achieving the film formation simulation method illustrated in FIG. 1 and FIG. 2.

### Configuration of Film Formation Simulation Program 2

A film formation simulation program 2 illustrated in FIG. 31 includes an input section 21, an arithmetic engine section 22, and a display section 23 to visualize simulation results. The arithmetic engine section 22 includes a gas flus calculation section 22a, a coverage calculation section 22b, a film quality calculation section 22c, and an output section 22d.

The input section 21 is implemented by a character-based user interface (CUI) or a graphical user interface (GUI) to set initial conditions. The input section 21 outputs values of the set initial conditions to the arithmetic engine section 22. The display section 23 is implemented by a GUI to visualize data obtained from the output section 22d.

The gas flux calculation section 22a calculates an incident radical flux entering surface voxels by executing the above-described Step S102 using the values of the initial conditions set by the input section 21. The coverage calculation section 22b calculates a shape and status of a film by executing the above-described Steps S103 to S109 using the value of incident radical flux calculated by the gas flux calculation section 22a. The film quality calculation section 22c calculates film quality by executing the above-described Steps S110 and S111 using the shape and status of the film obtained by the coverage calculation section 22b. The output section 22d outputs a simulation result of the predetermined film formation process calculated by the coverage calculation section 22b and the film quality calculation section 22c.

An execution platform of the film formation simulation program 2 may be any of Windows (registered trademark), Linux (registered trademark), Unix (registered trademark), or Mac (registered trademark), for example. Moreover, the GUIs used as the input section 21 and the display section 23 may use any configuration language such as OpenGL, Motif, and tcl/tk. A programming language of the arithmetic engine section 22 may be any type of programming language such as C, C++, Fortran, and JAVA (registered trademark). The film formation simulation program 2 may have a function of importing calculation results obtained by other simulators and passing them to the arithmetic engine section 22.

For example, recipe information, parameters for calculation, and pattern structure information are input as the initial conditions. After finishing the calculations by the coverage calculation section 22b and the film quality calculation section 22c, the output section 22d outputs material/coordinates of respective voxels, status (bonded state or unbound state)/film quality (film density, permeability, and adhesiveness) of the respective voxels, and a surface flux to a file or a temporary storage area. Further, these results may be also visualized by the GUI. The data may be output or visualized during the calculation in real time.

The film formation simulation program 2 according to this Example generates representative particles depending on an incident radical flux, and calculates adhesion, desorption, migration, and deposition of the respective representative particles to/from/on a film formation surface according to probability. This makes the accuracy and calculation time independent of the number of particles. In addition, according to this Example, through the above-described calculation, it is possible to expresses film quality and film coverage on the film formation surface by calculating the deposition as voxels imparted with status information indicating the bonded state or unbound state between the representative particles and the film formation surface. Accordingly, a database relying on morphology and a gas flux does not have to be separately prepared to calculate the film quality. This makes it possible to shorten the calculation time and improve the calculation accuracy. In addition, it is also expected to shorten turnaround time (TAT) before utilization of the algorithm according to this Example.

In this Example, the input section 21 is implemented by a CUI or a GUI to set the film formation conditions, and the output section 22d is implemented by a GUI to visualize the arithmetic results obtained by the coverage calculation section 22d and the film quality calculation section 22c. This allows the user to execute the film formation simulation program 2 in a relatively simple way, and to recognize the arithmetic results obtained by the film formation simulation program 2 in a relatively simple way.

### EXAMPLE 11

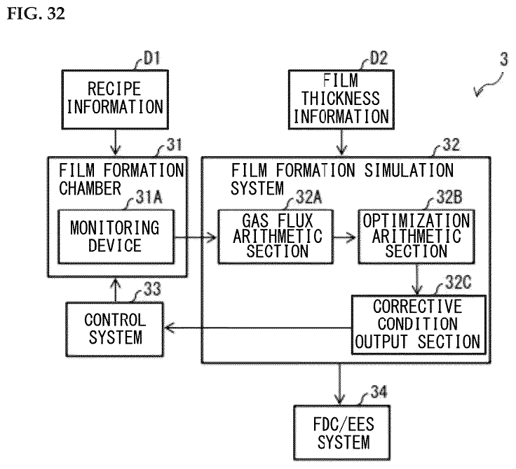

FIG. 32 illustrates a configuration example of a film formation device 3 to which the film formation simulation method (film formation simulation program 2) illustrated in FIG. 1 and FIG. 2 is applied.

### Configuration of Film Formation Device 3

FIG. 32 illustrates a conceptual diagram of the film formation device 3. The film formation device 3 includes a film formation chamber 31, a film formation simulation system 32, a control system 33, and a fault detection and classification/equipment engineering system (FDC/EES) system 34.

The film formation chamber 31 includes a monitoring device 31A that monitors the status in the chamber. For example, the monitoring device 31A includes an optical emission spectroscopy (OES). The OES is a measurement device that monitors light emitted from plasma in the chamber. When forming a film, light of wavelength specific to each gas species existing in the plasma is emitted. The OES measures the light. The OES measures light emission intensity for each wavelength. The OES specifies the gas species on the basis of the measured wavelength, and outputs information regarding the specified gas species as monitoring data. For example, the monitoring device 31A includes a system of monitoring the status in the chamber. The system measures temporal variation in gas pressure, flow rate, temperature, power, bias, matcher capacity, vacuum pump opening degree, or the like, and outputs data obtained through the measurement as monitoring data.

The film formation chamber 31 transmits the data (monitoring data) obtained by the monitoring device 31A to the film formation simulation system 32. The film formation simulation system 32 includes the film formation simulator 1 that executes the film formation simulation program 2. The film formation simulation system 32 includes a gas flux arithmetic section 32A, an optimization arithmetic section 32B, and a corrective condition output section 32C. The gas flux arithmetic section 32A, the optimization arithmetic section 32B, and the corrective condition output section 32C may be implemented by an integrated circuit, or may be implemented by an arithmetic device loaded with the film formation simulation program 2.

The gas flux arithmetic section 32A calculates the incident radical flux by using monitoring data input from the monitoring device 31A. By executing the above-described Steps S103 to S109 using the value of the incident radical flux obtained by the gas flux arithmetic section 32A, the optimization arithmetic section 32B generates representative particles depending on the value of the incident radical flux, and calculates adhesion, desorption, migration, and deposition of the respective representative particles to/from/on the film formation surface according to probability. This allows the optimization arithmetic section 32B to predict the shape and status of the film. In addition, the optimization arithmetic section 32B calculates film quality by executing the above-described Steps S110 and S111 using the obtained shape and status of the film.

The optimization arithmetic section 32B compares the calculated value (predicted value) obtained in such a way with a desired specification (for example, set film thickness information D2). In a case where the calculated value (predicted value) is out of an acceptable range, the optimization arithmetic section 32B search for an optimization condition for the film formation process to obtain a calculated value (predicted value) that falls within the acceptable range. Specifically, the optimization arithmetic section 32B changes the gas flow rate, gas pressure, substrate temperature, and processing time to find a solution from a predetermined algorithm. The optimization arithmetic section 32B searches for the optimization condition for each wafer or for each lot.
The optimization arithmetic section 32B transmits an abnormal signal to the FDC/EES system 34 in a case where no optimization condition has been found as a result. The FDC/EES system 34 outputs a signal for stopping the operation of the film formation chamber 31 to the control system 33 when the abnormal signal is received from the optimization arithmetic section 32B. The control system 33 stops the operation of the film formation chamber 31 when the signal for stopping the operation of the film formation chamber 31 is received.

Alternatively, in a case where the optimization condition is found, the optimization arithmetic section 32B outputs the found optimization condition to the corrective condition output section 32C. When the optimization condition is input, the corrective condition output section 32C generates data necessary for the film formation condition of the film formation chamber 31 to become the optimization condition and outputs the generated data to the control system 33. The control system 33 controls the operation of the film formation chamber 31 on the basis of the received data when the data necessary for the optimization condition is received. The control system 33 modifies recipe information D1 on the basis of the received data.

Concerning the optimization arithmetic section 32B, in a case where the calculation time has a scale equivalent to or larger than that of the actual processing time, an optimal solution may be found not online as described above but by a method (offline method) in which database simulated using the algorithm according to the Example 11 with respect to various process conditions is prepared in advance, the above-described Steps S103 to S109 are executed, by using a value of an incident radical flux predicted using the database, and the representative particles are generated depending on the value of the incident radical flux. Alternatively, it is also possible to construct a machine learning model by using the database and use the model as an online optimization arithmetic section 32B.

The film formation device 3 according to this Example generates representative particles depending on an incident radical flux, and calculates adhesion, desorption, migration, and deposition of the respective representative particles to/from/on a film formation surface according to probability. This makes the accuracy and calculation time independent of the number of particles. In addition, according to this Example, through the above-described calculation, it is possible to expresses film quality and film coverage on the film formation surface by calculating the deposition as voxels imparted with status information indicating the bonded state or unbound state between the representative particles and the film formation surface. Accordingly, a database relying on morphology and a gas flux does not have to be separately prepared to calculate the film quality. This makes it possible to shorten the calculation time and improve the calculation accuracy. In addition, it is also expected to shorten turnaround time (TAT) before utilization of the algorithm according to this Example.

In addition, in the film formation device 3 according to this Example, an optimization condition for a film formation process is searched for on the basis of a calculation result obtained through the above-described calculation, data necessary for the film formation condition of the film formation chamber to become the found optimization condition is generated, and the generated data is output to the control section 33. Such feedback makes it possible to manufacture semiconductor devices with higher quality.

In this Example, the monitoring device 31A monitors the status in the film formation chamber, and the incident radical flux is calculated by using monitoring data obtained by the monitoring device 31A. Such calculation using actually measured values makes it possible to manufacture semiconductor devices with higher quality.

In this Example, representative particles are generated depending on a value of the incident radical flux predicted by using a database. This makes it possible to manufacture semiconductor devices with higher quality even in a case where the calculation time has a scale equivalent to or larger than that of the actual processing time.

In this Example, the optimization condition for each wafer or for each lot is searched for. This makes it possible to manufacture semiconductor devices with higher quality for each wafer or for each lot.

The present disclosure has been described above with reference to the embodiment and the modifications thereof. However, the present disclosure is not limited thereto, and various kinds of modifications thereof can be made. It is to be noted that the effects described in the present specification are merely examples. The effects of the present disclosure are not limited to those described in the present specification. The present disclosure may include effects other than those described in the present specification.

For example, the present disclosure may be configured as follows.

(1)
A film formation simulation method including
a first step of generating representative particles depending on an incident radical flux, and calculating adhesion, desorption, migration, and deposition of the respective representative particles to/from/on a film formation surface according to probability,
in which the first step includes expressing film quality and film coverage on the film formation surface by calculating the deposition as voxels imparted with status information indicating a bonded state or unbound state between the representative particle and the film formation surface.
   (2)
The film formation simulation method according to (1), further including
a second step of calculating the incident radical flux on a basis of a gas component and a spread gas component, the gas component directly entering a voxel of an air region adjacent to the film formation surface, the spread gas component entering a voxel of the air region adjacent to the film formation surface in response to a surrounding structure.
   (3)
The film formation simulation method according to (1) or (2), in which the first step further includes determining whether the representative particles and the film formation surface are bonded or unbound, on a basis of energy and a flux of ions entering the voxel of the air region adjacent to the film formation surface.
   (4)
The film formation simulation method according to any one of (1) to (3), in which the first step further includes calculating film density, permeability, and adhesiveness to the film formation surface by using the status information.
   (5)
The film formation simulation method according to any one of (1) to (3), in which, in a case of forming a film by using a plurality of types of gas, the first step further includes calculating the number of representative particles generated by type of gas in a same time step.
   (6)
The film formation simulation method according to any one of (1) to (3), in which, in a case of forming a film by using a plurality of types of gas, the first step further includes calculating the number of representative particles generated by type of gas in different time steps.
   (7)
The film formation simulation method according to any one of (1) to (6), in which the first step further includes calculating a blister, film density, or both at a time of annealing after film formation.
   (8)
A film formation simulation program including:
an input section that acquires a film formation condition;
an arithmetic section that generates representative particles depending on an incident radical flux under the film formation condition acquired by the input section, and calculates adhesion, desorption, migration, and deposition of the respective representative particles to/from/on a film formation surface according to probability; and
an output section that outputs an arithmetic result obtained by the arithmetic section,
in which the arithmetic section expresses film quality and film coverage on the film formation surface by calculating the deposition as voxels imparted with status information indicating a bonded state or unbound state between the representative particle and the film formation surface.
   (9)
The film formation simulation program according to (8), in which
the input section is implemented by a character-based user interface (CUI) or a graphical user interface (GUI) to set the film formation condition, and
the output section is implemented by a GUI to visualize the arithmetic result obtained by the arithmetic section.
   (10)
A film formation simulator including:
an input section that acquires a film formation condition;
an arithmetic section that generates representative particles depending on an incident radical flux under the film formation condition acquired by the input section, and calculates adhesion, desorption, migration, and deposition of the representative particles to/from/on a film formation surface according to probability; and
an output section that outputs an arithmetic result obtained by the arithmetic section,
in which the arithmetic section expresses film quality and film coverage on the film formation surface by calculating the deposition as voxels imparted with status information indicating a bonded state or unbound state between the representative particles and the film formation surface.
   (11)
The film formation simulator according to (10), in which
the input section is implemented by a character-based user interface (CUI) or a graphical user interface (GUI) to set a film formation condition, and
the output section is implemented by a GUI to visualize the arithmetic result obtained by the arithmetic section.
   (12)
A film formation device including:
a film formation chamber;
a control section that controls operation of the film formation chamber;
an optimization arithmetic section that generates representative particles depending on a value of an incident radical flux, calculates adhesion, desorption, migration, and deposition of the respective representative particles to/from/on a film formation surface according to probability, and searches for an optimization condition for a film formation process on a basis of a calculation result obtained thereby; and
an output section that generates data necessary for the film formation condition of the film formation chamber to become the optimization condition found by the optimization arithmetic section and outputs the generated data to the control section,
in which the optimization arithmetic section expresses film quality and film coverage on the film formation surface by calculating the deposition as voxels imparted with status information indicating a bonded state or unbound state between the representative particles and the film formation surface.
   (13)
The film formation device according to (12), further including:
a monitoring device that monitors a status in the film formation chamber; and
a gas flux arithmetic section that calculates the incident radical flux by using monitoring data obtained by the monitoring device.
   (14)
The film formation device according to (12), in which the optimization arithmetic section generates a representative particle depending on a value of the incident radical flux predicted by using a database.
   (15)
The film formation device according to any one of (12) to (14), in which the optimization arithmetic section searches for the optimization condition for each wafer or for each lot.

The present application claims the benefit of Japanese Priority Patent Application JP2022-094465 filed with the Japan Patent Office on Jun. 10, 2022, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A film formation simulation method comprising
a first step of generating representative particles depending on an incident radical flux, and calculating adhesion, desorption, migration, and deposition of the respective representative particles to/from/on a film formation surface according to probability,
wherein the first step includes expressing film quality and film coverage on the film formation surface by calculating the deposition as voxels imparted with status information indicating a bonded state or unbound state between the representative particle and the film formation surface.

2. The film formation simulation method according to claim 1, further comprising
a second step of calculating the incident radical flux on a basis of a gas component and a spread gas component, the gas component directly entering a voxel of an air region adjacent to the film formation surface, the spread gas component entering a voxel of the air region adjacent to the film formation surface in response to a surrounding structure.

3. The film formation simulation method according to claim 1, wherein the first step further includes determining whether the representative particles and the film formation surface are bonded or unbound, on a basis of energy and a flux of ions entering the voxel of the air region adjacent to the film formation surface.

4. The film formation simulation method according to claim 1, wherein the first step further includes calculating film density, permeability, and adhesiveness to the film formation surface by using the status information.

5. The film formation simulation method according to claim 1, wherein, in a case of forming a film by using a plurality of types of gas, the first step further includes calculating the number of representative particles generated by type of gas in a same time step.

6. The film formation simulation method according to claim 1, wherein, in a case of forming a film by using a plurality of types of gas, the first step further includes calculating the number of representative particles generated by type of gas in different time steps.

7. The film formation simulation method according to claim 1, wherein the first step further includes calculating a blister, film density, or both at a time of annealing after film formation.

8. A film formation simulation program comprising:
an input section that acquires a film formation condition;
an arithmetic section that generates representative particles depending on an incident radical flux under the film formation condition acquired by the input section, and calculates adhesion, desorption, migration, and deposition of the respective representative particles to/from/on a film formation surface according to probability; and
an output section that outputs an arithmetic result obtained by the arithmetic section,
wherein the arithmetic section expresses film quality and film coverage on the film formation surface by calculating the deposition as voxels imparted with status information indicating a bonded state or unbound state between the representative particle and the film formation surface.

9. The film formation simulation program according to claim 8, wherein
the input section is implemented by a character-based user interface (CUI) or a graphical user interface (GUI) to set the film formation condition, and
the output section is implemented by a GUI to visualize the arithmetic result obtained by the arithmetic section.

10. A film formation simulator comprising:
an input section that acquires a film formation condition;
an arithmetic section that generates representative particles depending on an incident radical flux under the film formation condition acquired by the input section, and calculates adhesion, desorption, migration, and deposition of the representative particles to/from/on a film formation surface according to probability; and
an output section that outputs an arithmetic result obtained by the arithmetic section,
wherein the arithmetic section expresses film quality and film coverage on the film formation surface by calculating the deposition as voxels imparted with status information indicating a bonded state or unbound state between the representative particles and the film formation surface.

11. The film formation simulator according to claim 10, wherein
the input section is implemented by a character-based user interface (CUI) or a graphical user interface (GUI) to set a film formation condition, and
the output section is implemented by a GUI to visualize the arithmetic result obtained by the arithmetic section.

12. A film formation device comprising:
a film formation chamber;
a control section that controls operation of the film formation chamber;
an optimization arithmetic section that generates representative particles depending on a value of an incident radical flux, calculates adhesion, desorption, migration, and deposition of the respective representative particles to/from/on a film formation surface according to probability, and searches for an optimization condition for a film formation process on a basis of a calculation result obtained thereby; and
an output section that generates data necessary for the film formation condition of the film formation chamber to become the optimization condition found by the optimization arithmetic section and outputs the generated data to the control section,
wherein the optimization arithmetic section expresses film quality and film coverage on the film formation surface by calculating the deposition as voxels imparted with status information indicating a bonded state or unbound state between the representative particles and the film formation surface.

13. The film formation device according to claim 12, further comprising:
a monitoring device that monitors a status in the film formation chamber; and
a gas flux arithmetic section that calculates the incident radical flux by using monitoring data obtained by the monitoring device.

14. The film formation device according to claim 12, wherein the optimization arithmetic section generates a representative particle depending on a value of the incident radical flux predicted by using a database.

15. The film formation device according to claim 12, wherein the optimization arithmetic section searches for the optimization condition for each wafer or for each lot.
